(19) United States
(12) Patent Application Publication
(10) Pub. No.: US 2006/0084208 A1
(43) Pub. Date: Apr. 20, 2006

(54) Semiconductor device and its manufacture method

(76) Inventors: Masayoshi Asano, Kawasaki (JP); Toshio Nomura, Kawasaki (JP); Taiji Ema, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 11/242,648

(22) Filed: Oct. 4, 2005

Related U.S. Application Data
(63) Continuation of application No. PCT/JP03/04326, filed on Apr. 4, 2003.

(51) Int. Cl. H01L 21/337

(52) U.S. Cl. 438/195

(57) ABSTRACT

A simplified method of manufacturing a multi-voltage semiconductor integrated circuit device. A method of manufacturing a semiconductor device includes the steps of: forming a first gate insulating film with a first thickness in a first area of a semiconductor substrate: forming a second gate insulating film with a second thickness thinner than the first thickness in a second area of the semiconductor substrate; forming on gate electrodes on the first and second gate insulating films and leaving the first and second gate insulating films in the first and second areas; implanting impurity ions into the first and second areas via the first and second gate insulating films to dope impurities into the first area at a first low impurity concentration and into the second area at a second impurity concentration higher than the first impurity concentration; removing the first and second gate insulating films at least in an area where contacts are formed; and doping impurities at a high impurity concentration in an area including the area where contacts are formed, in the first and second areas.

### CROSS REFERENCE TO RELATED APPLICATION

This application is a continuation application of a PCT application PCT/JP2003/004326 filed on Apr. 4, 2003, designating United States of America, the whole contents of which are incorporated herein by reference.

### BACKGROUND OF THE INVENTION

A) Field of the Invention

The present invention relates to a semiconductor device and its manufacture method, and more particularly to a semiconductor device having a high voltage transistor with a first breakdown voltage (withstanding voltage) and a low voltage transistor with a second breakdown voltage (withstanding voltage) lower than the first breakdown voltage formed on the same semiconductor substrate and to its manufacture method.

B) Description of the Related Art

A high voltage is applied to the drain of a high voltage transistor relative to the source, and is also applied to the gate. A withstanding voltage of the drain junction is required to be a power source voltage or higher. When a high voltage is applied to both the drain and gate, hot carriers of an opposite conductivity type generated by collision ionization flow into an opposite conductivity type substrate so that a potential of the substrate rises. A withstanding voltage of a power source voltage or higher is therefore required for a parasitic bipolar operation generating a parasitic operation like conduction through a bipolar transistor.

It is widely known that in order to raise a breakdown voltage of the drain, an n⁻-type offset region having a low impurity concentration is disposed between, for example, a p-type channel region under the gate electrode and an n⁺-type drain region having a high impurity concentration. In this case, an electric field near the drain junction is weakened by lowering the impurity concentration of the offset region, so that generation of collision ionization can be suppressed. However, if an impurity concentration difference between the offset region and the drain region having the high impurity concentration becomes large, an electric field becomes high near at the interface between the offset region and the drain region having the high impurity concentration, so that a parasitic bipolar operation is likely to occur.

It has been proposed that a low impurity concentration n⁻-type region and an intermediate impurity concentration n⁻-type region are interposed between the p-type channel region and the n⁺-type drain region having a high impurity concentration (e.g., JP-A-HEI-5-218070, JP-A-HEI-6-232153).

There is a case wherein high voltage transistors and transistors having a lower drain withstanding voltage are integrated. For example, there is a request for using voltage in the order of 40 V and voltage in the order of 10 V to control the voltage of a vehicle mounted battery. There is also a request for using high withstanding voltage transistors and transistors having a lower drain withstanding voltage, in a display device such as a liquid crystal display device and an organic EL device.

It has not been elucidated how manufacture processes can be simplified for such a multi-voltage semiconductor integrated circuit device using a plurality of voltages including a high voltage.

### DISCLOSURE OF THE INVENTION

It is an object of the present invention to provide a multi-voltage semiconductor integrated circuit device capable of being manufactured with simplified processes.

It is another object of the present invention to provide a simplified manufacture method for a multi-voltage semiconductor integrated circuit device.

It is still another object of the present invention to provide a multi-voltage semiconductor integrated circuit device having a novel structure.

It is another object of the present invention to provide a manufacture method for a multi-voltage semiconductor integrated circuit device capable of forming different functional blocks with the same process.

According to one aspect of the present invention, there is provided a semiconductor device manufacture method comprising steps of: (a) forming a first gate insulating film having a first thickness in a first region of a semiconductor substrate; (b) forming a second gate insulating film having a second thickness thinner than the first thickness in a second region of the semiconductor substrate; (c) forming a gate electrode on the first and second gate insulating films and leaving the first and second gate insulating films in the first and second regions; (d) implanting impurity ions into the first and second regions via the first and second gate insulating films to dope impurity ions in the first region at a first low concentration and in the second region at a second low concentration higher than the first low concentration; (e) removing the first and second gate insulating films at least in regions where contacts are to be formed; and (f) after removing the first and second gate insulating films, doping impurities at a high concentration in a region including the regions where the contacts are to be formed.

According to another aspect of the present invention, there is provided a semiconductor device comprising: a semiconductor substrate; an element isolation region formed on a surface of the semiconductor substrate, the element isolation region defining first and second element regions; a first gate insulating film formed on a surface of the first region and having a first thickness; a second gate insulating film formed on a surface of the second region and having a second thickness thinner than the first thickness; first and second gate electrode structures formed on the first and second gate insulating films and having first and second gate electrodes and first and second side wall spacers formed on side walls of the first and second gate electrodes; a first low concentration region formed in the first element region outward from an edge of the first gate electrode; a second low concentration region formed in the second element region outward from an edge of the second gate electrode; a first intermediate concentration region formed spaced from the edge of the first gate electrode continuously with the first low concentration region in the first region; and first and second high concentration regions formed continuously with the first intermediate region and the second low concentration region in the first and second regions, wherein a total sum of impurities doped in the first gate insulating film under the first side wall spacers and the first region under the first gate insulating film is equal to a total sum of impurities doped in the second gate insulating film under second side wall spacers and the second region under the second gate insulating film.

According to still another aspect of the present invention, there is provided a semiconductor device comprising: a semiconductor substrate; an element isolation region formed on a surface of the semiconductor substrate, the element isolation region defining first and second element regions; a first gate insulating film formed on a surface of the first region and having a first thickness; a second gate insulating film formed on a surface of the second region and having a second thickness thinner than the first thickness; first and second gate electrode structures formed on the first and second gate insulating films and having first and second gate electrodes and first and second side wall spacers formed on side walls of the first and second gate electrodes; a first low concentration region formed in the first element region outward from an edge of the first gate electrode; a second low concentration region formed in the second element region outward from an edge of the second gate electrode; and first and second high concentration regions formed continuously with the first intermediate region and the second low concentration region in the first and second regions, wherein a total sum of impurities doped in the first gate insulating film under the first side wall spacers and the first region under the first gate insulating film is equal to a total sum of impurities doped in the second gate insulating film under second side wall spacers and the second region under the second gate insulating film. BRIEF DESCRIPTION OF THE DRAWINGS

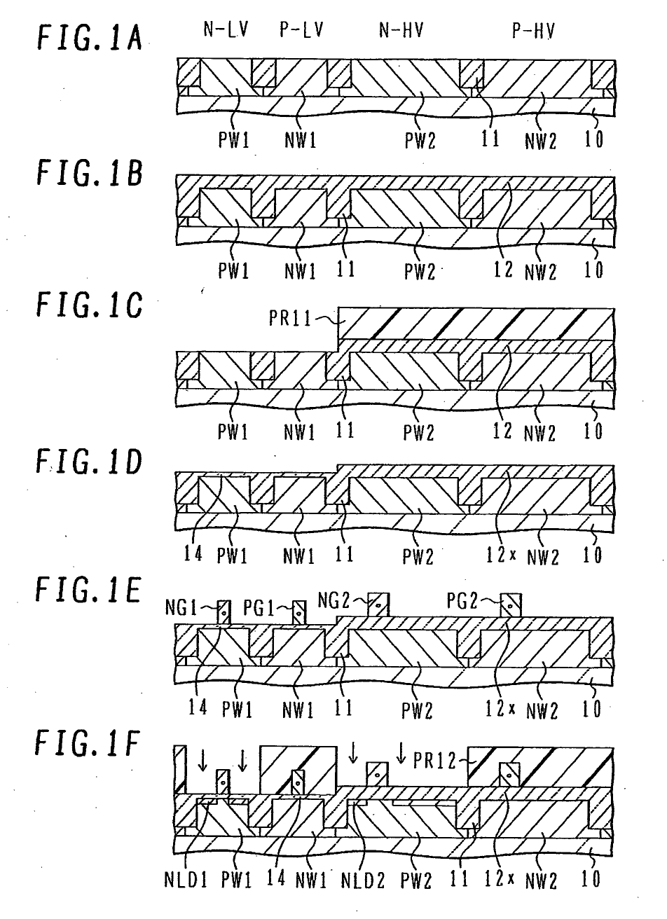

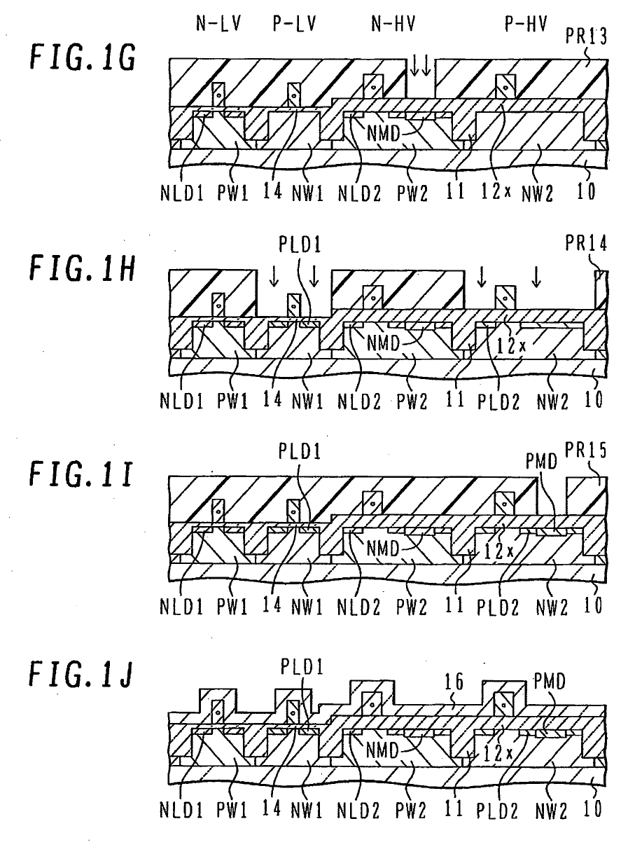

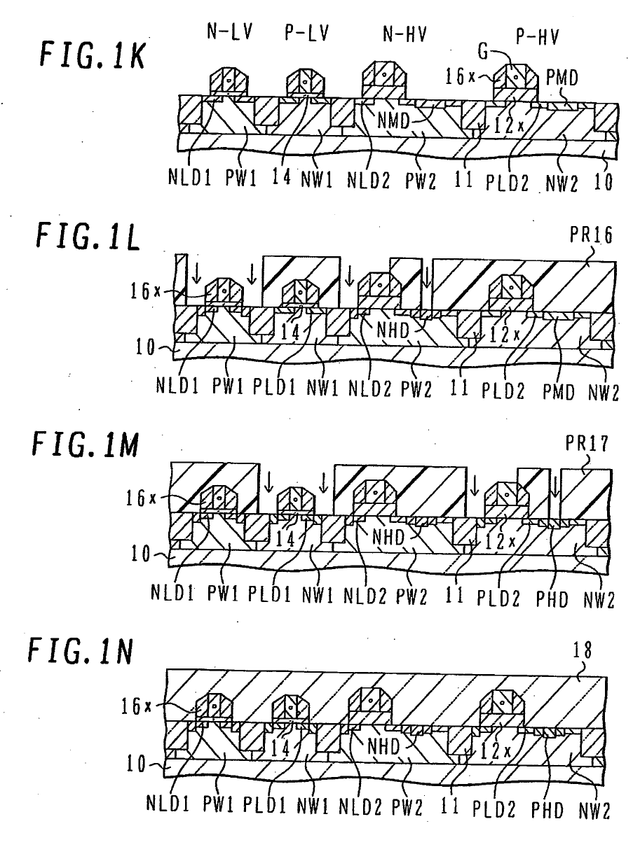

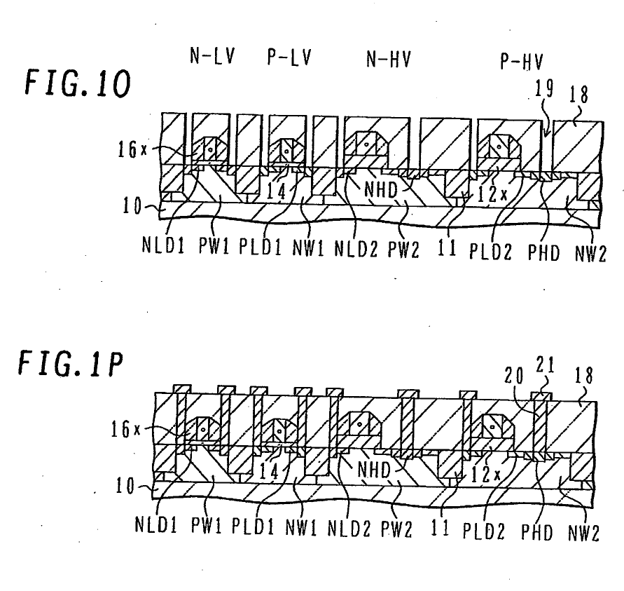

FIGS. 1A to 1P are cross sectional views illustrating main processes of a semiconductor device manufacture method according to a first embodiment of the present invention.

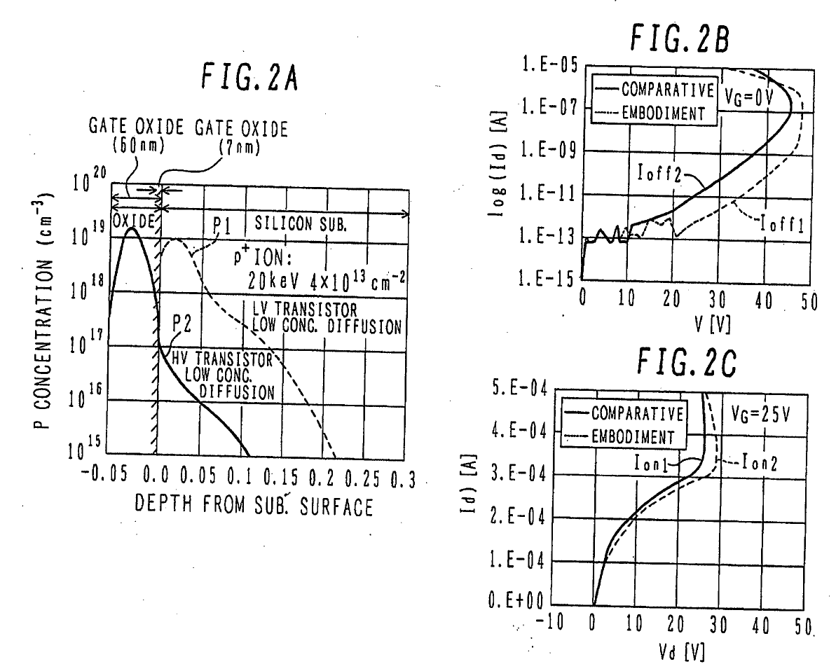

FIGS. 2A to 2C are a graph showing impurity concentration distributions of two types of impurity diffusion regions formed at the same time by a process shown in FIG. 1F, and graphs showing the relation between drain current and drain voltage in an off-state and an on-state of high voltage transistors.

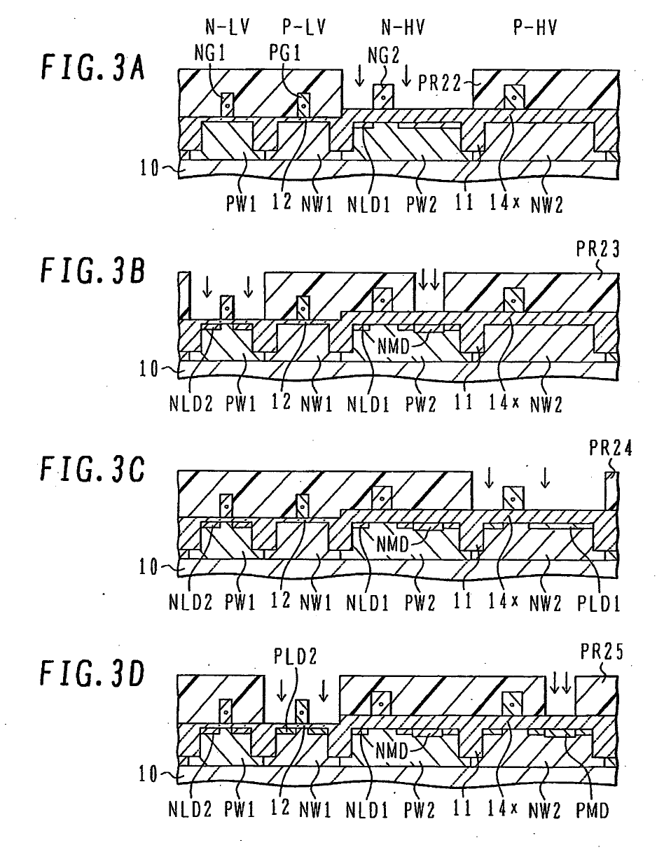

FIGS. 3A to 3D are cross sectional views illustrating main processes of a semiconductor device manufacture method according to a second embodiment of the present invention.

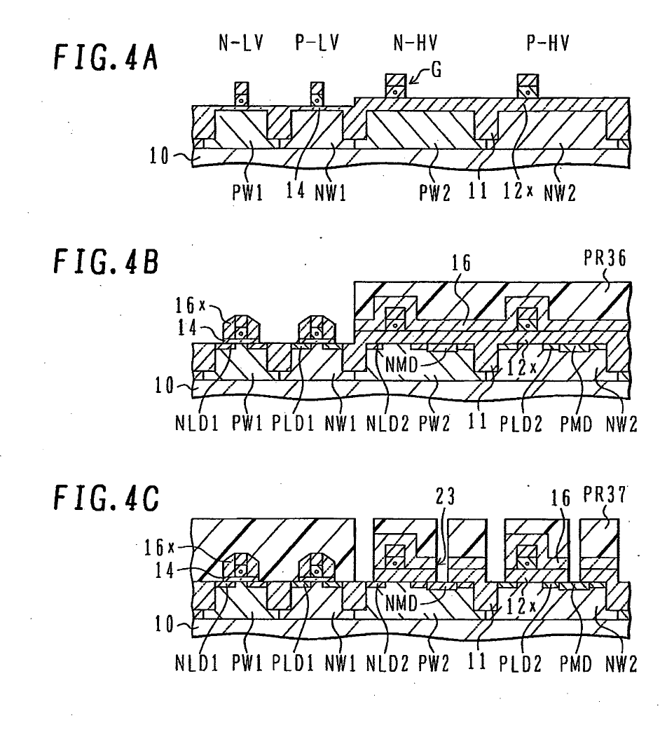

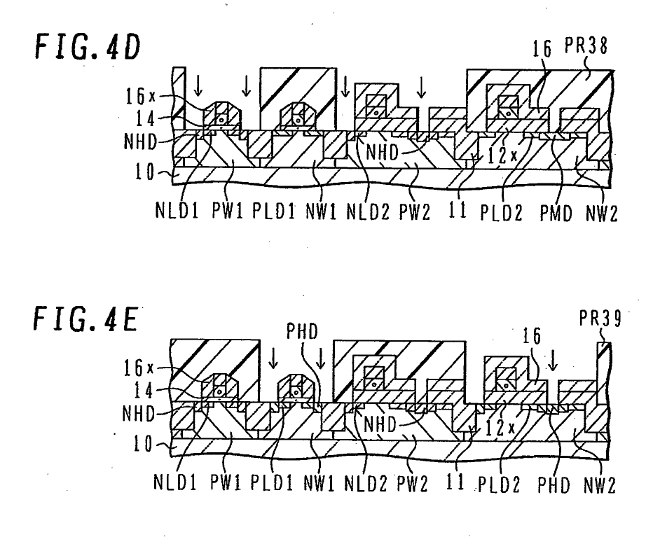

FIGS. 4A to 4E are cross sectional views illustrating main processes of a semiconductor device manufacture method according to a third embodiment of the present invention.

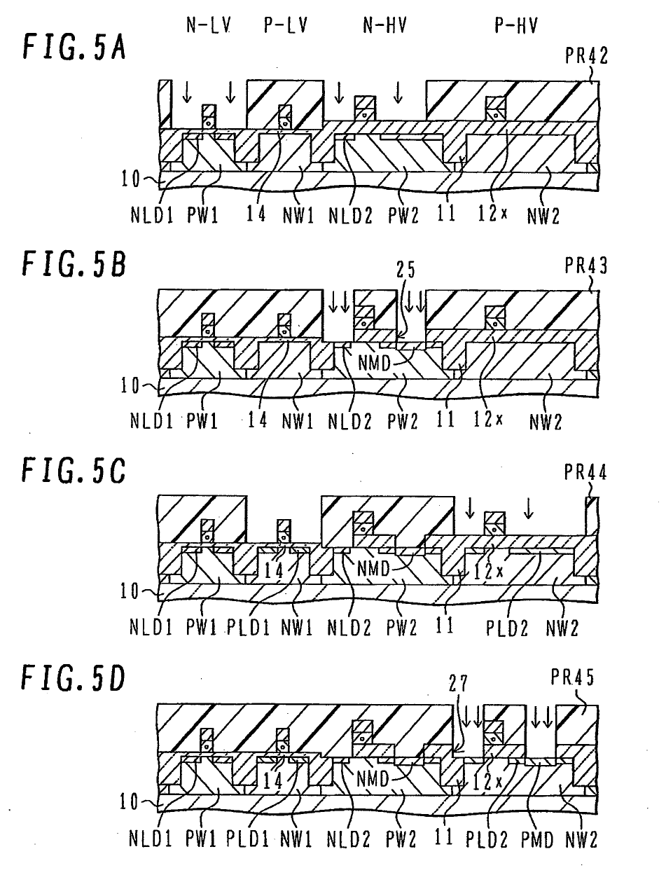

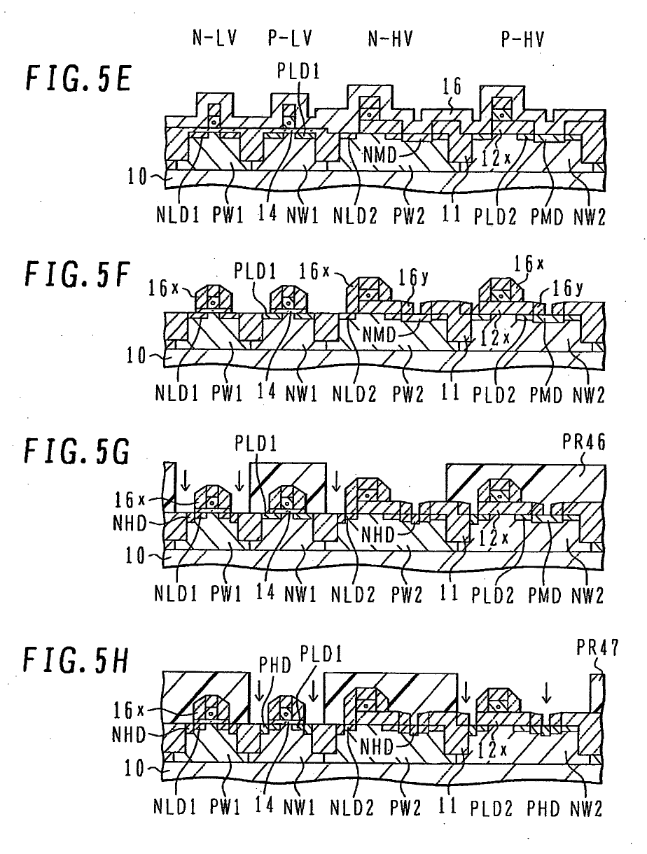

FIGS. 5A to 5H are cross sectional views illustrating main processes of a semiconductor device manufacture method according to a fourth embodiment of the present invention.

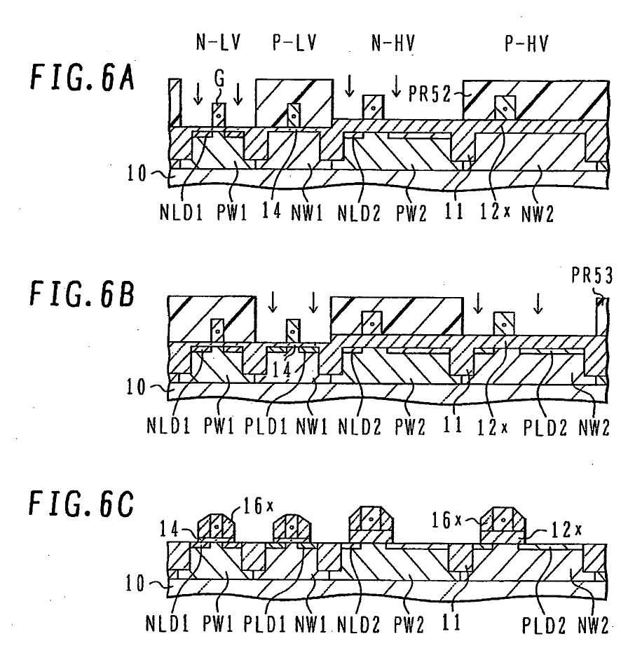

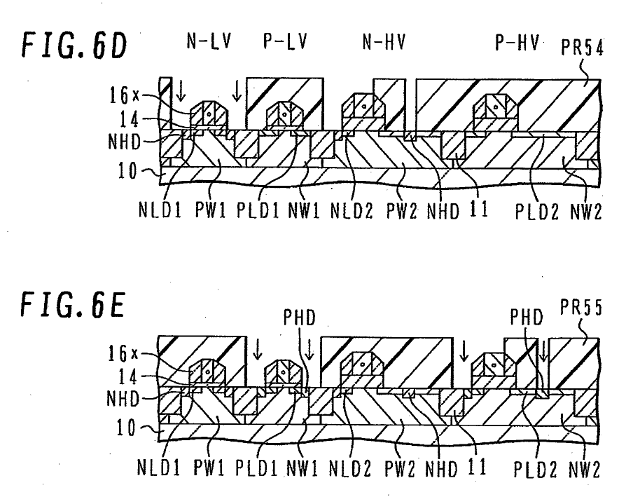

FIGS. 6A to 6E are cross sectional views illustrating main processes of a semiconductor device manufacture method according to a fifth embodiment of the present invention.

### BEST MODE FOR CARRYING OUT THE INVENTION

Embodiments of the present invention will be described with reference to the drawings.

FIGS. 1A to 1P are cross sectional views illustrating main processes of a semiconductor device manufacture method according to the first embodiment of the present invention.

As shown in FIG. 1A, an element isolation region 11 is formed in the surface layer of a semiconductor substrate 10 by shallow trench isolation (STI). Instead of STI, local oxidation of silicon (LOCOS) may be used. Ion implantation is performed relative to active regions defined by the element isolation region 11 to form desired wells.

In the structure shown in FIG. 1A, there are shown a p-well PW1 for forming an n-channel low voltage transistor (N-LV), an n-well NW1 for forming a p-channel low voltage transistor (P-LV), a p-well PW2 for forming an n-channel high voltage transistor (N-HV), and an n-well NW2 for forming a p-channel high voltage transistor (P-HV). Necessary channel stops and threshold voltage adjusting regions are formed in each well.

As shown in FIG. 1B, in order to form a gate insulating film of the high voltage transistor, the surface of the semiconductor substrate 10 is thermally oxidized, e.g., at 1000 ° C. to form a thick gate insulating film 12 having a thickness of 60 nm on the active region surface.

As shown in FIG. 1C, the high voltage transistor region is covered with a photoresist mask PR11 and the gate insulating film 12 in the low voltage transistor region is etched and removed. The photoresist mask PR11 is thereafter removed.

As shown in FIG. 1D, the surface of the semiconductor substrate 10 is thermally oxidized at 800° C. to form a thin gate insulating film 14 having a thickness of 7 nm on the surface of the low voltage transistor region. With this thermal oxidation, the thick gate insulating film 12 grows slightly and becomes a gate insulating film 12x.

As shown in FIG. 1E, an amorphous silicon layer doped with phosphorous (P) at 0.1×10²¹ cm⁻³ is deposited on the gate insulating films 12x and 14 at 530° C. to a thickness of 90 nm. Instead of depositing the doped amorphous silicon layer, a non-doped amorphous silicon layer may be deposited and thereafter, n-type and p-type impurity ions are separately implanted for n- and p-channel transistors by using resist masks.

The amorphous silicon layer is patterned to form low voltage transistor gate electrodes NG1 and PG1 having a gate length of 0.34 μm and high voltage transistor gate electrodes NG2 and PG2 having a gate length of 2.0 μm.

As shown in FIG. 1F, a photoresist mask PR12 is formed covering the p-channel transistor regions P-LV and P-HV. P⁺ ions are implanted into the n-channel transistor regions N-LV and N-HV via the gate insulating films 14 and 12x having different thicknesses at an acceleration energy of 20 keV and a dose of 4×10¹³ cm⁻². The photoresist mask PR12 is thereafter removed.

FIG. 2A is a graph showing concentration distribution in the substrate depth direction of phosphorus (P) implanted into the two transistor regions at the same acceleration energy of 20 keV and the same dose of 4×10¹³ cm⁻². The gate oxide film of the low voltage transistor was set to 7 nm in thickness, and the gate oxide film of the high voltage transistor was set to 60 nm in thickness. The abscissa represents a position of the substrate in the depth direction, 0 indicating the substrate surface. The oxide films having different thicknesses are formed in a minus direction of the abscissa.

In the low voltage transistor region N-LV, since the gate insulating film is as thin as 7 nm, the P concentration has a peak of about 10¹⁹ cm⁻³ just under the silicon substrate surface and a relatively high concentration distribution. In the high voltage transistor region N-HV, an impurity concentration peak of about 10¹⁹ cm⁻³ is formed in the gate insulating film having the thickness of 60 nm, and the impurity concentration lowers by about two digits at the silicon substrate surface. At the deeper position, the P concentration lowers further.

Both the low voltage transistor region N-LV and high voltage transistor region N-HV are the silicon substrate covered with the silicon oxide layer, and a total sum of the amount of impurities implanted into the silicon oxide layer and the amount of impurities implanted into the silicon substrate is the same in both the regions.

In this manner, with the same ion implantation, a relatively high impurity concentration distribution P1 is obtained in the low voltage transistor region N-LV, and a relatively low impurity concentration distribution P2 is obtained in the high voltage transistor region N-HV. In this manner, low concentration impurity diffusion regions NLD1 and NLD2 are formed which are suitable for the low voltage and high voltage n-channel transistor regions.

As shown in FIG. 1G, a photoresist mask PR13 is formed having an opening in the region in which an intermediate concentration impurity diffusion region of the high voltage transistor region N-HV is formed. P⁺ ions are implanted at an acceleration energy of 100 keV and a dose of 2×10¹² cm⁻² to form an intermediate concentration impurity diffusion region NMD. The photoresist mask PR13 is thereafter removed.

As shown in FIG. 1H, a photoresist mask PR14 is formed exposing the p-channel transistor regions P-LV and P-HV. BF₂⁺ ions are implanted via the thin gate insulating film 14 and thick gate insulating film 12x at an acceleration energy of 35 keV and a dose of 3×10¹³ cm⁻². The photoresist mask PR14 is thereafter removed. Similar to ion implantation in FIG. 1F, B ions implanted into the low voltage transistor P-LV via the thin gate insulating film 14 form low concentration impurity diffusion regions PLD1 of a relatively high concentration, whereas B ions implanted via the thick gate insulating film 12x form low concentration impurity diffusion regions PLD2 of a relatively low impurity concentration. As shown in FIG. 11, a photoresist mask PR15 is formed having an opening corresponding to the intermediate concentration impurity diffusion region in the p-channel high voltage transistor region P-HV. B⁺ ions are implanted at an acceleration energy of 45 keV and a dose of 1×10¹² cm⁻² to form an intermediate concentration impurity diffusion region PMD. The photoresist mask PR15 is thereafter removed.

The ion implantation for the intermediate concentration diffusion regions shown in FIGS. 1G and 1I may be performed after the silicon substrate surface is exposed.

As shown in FIG. 1J, the substrate is heated to 800° C. to deposit a silicon oxide film 16 having a thickness of about 120 nm, by thermal-chemical vapor deposition (CVD). With this thermal CVD, the silicon oxide layer 16 can be formed on the side walls of the gate electrodes with good coverage.

As shown in FIG. 1K, reactive ion etching (RIE) is performed relative to the whole substrate surface to etch the silicon oxide layer 16 on the flat surface and the gate insulating films 12x and 14 by a thickness of 120 nm+60 nm=180 nm. Side wall spacers 16x are therefore formed on the side walls of the gate electrodes G, and the gate insulating films 12x and 14 are left under the gate electrodes G and side wall spacers 16x.

As shown in FIG. 1L, a photoresist mask PR16 is formed having openings in the regions formed in which are high concentration impurity diffusion regions in the n-channel transistor regions. In the low voltage transistor region N-LV, the whole transistor region is exposed in the opening. In the high voltage transistor region N-HV, the photoresist mask PR16 is formed in the region from the gate electrode to the region where an intermediate concentration impurity diffusion region is formed, and the opening is formed only in the region where a high concentration impurity diffusion region is formed.

By using as a mask the photoresist mask PR16, gate electrodes and side wall spacers, As⁺ ions are implanted at an acceleration energy of 30 keV and a dose of 1×10¹⁵ cm⁻² to form high concentration impurity diffusion regions NHD. The photoresist mask PR16 is thereafter removed.

In the high voltage transistor region N-HV, the high concentration impurity diffusion region NHD is formed next to the intermediate concentration impurity diffusion region NMD via the low concentration impurity diffusion region NLD and the side edge of the gate electrode.

As shown in FIG. 1M, a photoresist mask PR17 is formed having an opening in the region corresponding to the high concentration impurity diffusion region in the p-channel transistor region. BF₂⁺ ions are implanted at an acceleration energy of 20 keV and a dose of 3×10¹⁵ cm⁻² to form high concentration impurity diffusion regions PHD. The photoresist mask PR17 is thereafter removed.

In the high voltage transistor region P-HV, the high concentration impurity diffusion region PHD is formed next to the intermediate concentration impurity diffusion region PMD via the low concentration impurity diffusion region PLD and the side edge of the gate electrode.

In this manner, by forming the intermediate concentration impurity diffusion region and the high concentration impurity diffusion region through ion implantation using masks, the low and intermediate concentration impurity diffusion regions can be formed having desired concentrations and sizes.

As shown in FIG. 1N, a silicon oxide layer 18 is deposited by CVD, covering the gate electrodes, and the surface of the silicon oxide layer is planarized by chemical mechanical polishing (CMP).

As shown in FIG. 1O, contact holes 19 are formed through the silicon oxide layer 18 by using a photoresist mask.

As shown in FIG. 1P, for example, a Ti layer, a TiN layer and a W layer are deposited burying the contact holes, and unnecessary metal layers on the silicon oxide layer 18 are removed by CMP or the like to form tungsten plugs 20 in the contact holes. Thereafter, aluminum wiring layer is deposited on the surface of the silicon oxide layer 18 to form aluminum wirings 21. Thereafter, if necessary, an interlayer insulating film and a wiring are repetitively formed to form a multi-layer wiring structure.

FIGS. 2B and 2C show the simulated characteristics of a high voltage transistor formed by the first embodiment. FIG. 2B shows the characteristics of an off-state when the gate voltage V_{G}=0 V, and FIG. 2C shows the characteristics of an on-state when the gate voltage V_{G}=25 V. The abscissa represents a drain voltage Vd and the ordinate represents a drain current Id. In FIG. 2B, the ordinate is a logarithmic scale.

The characteristics of a comparative example are also shown together with the characteristics of the embodiment. The comparative example was formed by removing the gate insulating film when the gate electrodes are patterned, implanting P⁺ ions directly into the surface layer of the silicon substrate at an acceleration energy of 20 keV and a dose of 2×10¹² cm⁻² to form the low concentration impurity diffusion region, and implanting P⁺ ions at an acceleration energy of 20 keV and a dose of 2×10¹² cm⁻² to form the low concentration impurity diffusion region. The high concentration impurity diffusion region was formed by a process similar to that of the first embodiment.

It can be seen that although the manufacture processes of the first embodiment are simplified, the performance generally equal to that of the comparative example can be obtained. Although the characteristics of the first embodiment seem to be superior in the graphs, this depends on setting conditions and is considered not as a significant difference.

FIGS. 3A to 3D are cross sectional views illustrating main processes of a semiconductor device manufacture method according to the second embodiment. First, similar to the first embodiment, the processes shown in FIGS. 1A to 1E are executed to pattern gate electrodes on the gate insulating films having different thicknesses.

As shown in FIG. 3A, a photoresist mask PR22 is formed having an opening in a region corresponding to an n-channel high voltage transistor region N-HV. P⁺ ions are implanted at an acceleration of 100 keV and a dose of 1.3×10¹² cm⁻² to form desired low concentration impurity diffusion regions NLD1. The photoresist mask PR22 is thereafter removed.

As shown in FIG. 3B, a photoresist mask PR23 is formed having openings in the regions corresponding to an n-channel low voltage transistor region N-LV and an intermediate concentration impurity diffusion region in an n-channel high voltage transistor region N-HV. By using the photoresist mask PR23 as a mask, P⁺ ions are implanted at an acceleration energy of 20 keV and a dose of 4×10¹³ cm⁻² to form low concentration regions NLD2 in the low voltage transistor region N-LV and to form intermediate impurity diffusion regions NMD, overlapping the low impurity concentration region in the high voltage transistor region N-HV. A desired low concentration can be selected because an impurity concentration of the low concentration impurity diffusion region in the high voltage transistor region can be determined freely.

As shown in FIG. 3C, a photoresist mask PR24 is formed opening a p-channel high voltage transistor region P-HV. B⁺ ions are implanted at an acceleration energy of 45 keV and a dose of 1×10¹² cm⁻² to form low concentration impurity diffusion regions PLD1. The photoresist mask PR24 is thereafter removed.

As shown in FIG. 3D, a photoresist mask PR25 is formed opening the whole area of a p-channel low voltage transistor region P-LV and an intermediate concentration impurity diffusion region of the p-channel high voltage transistor region P-HV. BF₂⁺ ions are implanted at an acceleration energy of 35 keV and a dose of 3×10¹³ cm⁻² to form low concentration impurity diffusion regions PLD2 of the low voltage transistor and an intermediate concentration impurity diffusion region PMD of the high voltage transistor. Thereafter, the process of depositing a silicon oxide film shown in FIG. 1J and subsequent processes are executed in a manner similar to the first embodiment to complete the semiconductor device.

In the first embodiment, the gate insulating films are etched at the same time when the side wall spacers are formed. As the gate insulating films having different thicknesses are etched, over-etching is performed in the low voltage transistor region having a thin gate insulating film. The characteristics of the low voltage transistor may be adversely affected by over-etching. The influence of over-etching becomes larger as the insulating film becomes thicker.

FIGS. 4A to 4E are cross sectional views illustrating main processes of a semiconductor device manufacture method according to the third embodiment.

The structure shown in FIG. 4A is obtained by executing similar processes to those shown in FIGS. 1A to 1E. In this embodiment, however, a thick gate insulating film having a thickness of 120 nm is first formed by thermal oxidation at 1000 ° C., and then a thin gate insulating film 14 having a thickness of 9 nm is formed by thermal oxidation at 1050 ° C. In this manner, the gate insulating films 12x and 14 are formed which are thicker than those of the first embodiment. A thickness difference between the gate insulating films increases by 120−9=111 nm. Gate electrodes G are made of a lamination of a silicon layer having a thickness of 120 nm and a WSi layer having a thickness of 100 nm. The gate of a low voltage transistor is set to have a gate length of 0.6 μm and the gate of a high voltage transistor is set to have a gate length of 2.0 μm.

As shown in FIG. 4B, P⁺ ions are implanted at an acceleration energy of 60 keV and a dose of 3×10¹³ cm⁻² to form low concentration impurity diffusion regions NLD1 and NLD2. For an intermediate concentration impurity diffusion region, P⁺ ions are implanted at an acceleration energy of 120 keV. The dose is determined depending upon desired characteristics.

For a p-channel transistor region, BF₂⁺ ions are implanted at an acceleration energy of 60 keV and a dose of 8×10¹³ cm⁻² to form low concentration regions PLD1 and PLD2. For an intermediate concentration region of the high voltage transistor, B⁺ ions are implanted at an acceleration energy of 120 keV. The dose is determined depending upon desired characteristics. Thereafter, a silicon oxide layer 16 having a thickness of 150 nm is formed by thermal CVD at 800° C.

A photoresist mask PR36 is formed covering the high voltage transistor region. RIE is executed relative to the low voltage transistor region to form side wall spacers 16x. In the high voltage transistor region, the surfaces of the gate electrodes and substrate continue to be covered with the silicon oxide layer 16. The photoresist mask PR36 is thereafter removed.

As shown in FIG. 4C, a photoresist mask PR37 is formed having openings in the regions corresponding to contact regions of the high voltage transistor region. The silicon oxide layer 16 and gate insulating gate insulating film 12x are etched to expose the silicon substrate surface. The photoresist mask PR37 is thereafter removed.

As shown in FIG. 4D, a photoresist mask PR38 is formed opening the n-channel transistor regions. As⁺ ions are implanted at an acceleration energy of 70 keV and a dose of 4×10¹⁵ cm⁻² to form high concentration impurity diffusion regions NHD. The photoresist mask PR38 is thereafter removed.

As shown in FIG. 4E, a photoresist mask PR39 is formed opening the p-channel transistor regions. BF₂⁺ ions are implanted at an acceleration energy of 60 keV and a dose of 3.5×10¹⁵ c⁻² to form high concentration impurity diffusion regions PHD. The photoresist mask PR39 is thereafter removed. Thereafter, the process shown in FIG. 1N and subsequent processes are executed in a manner similar to the first embodiment to complete the semiconductor device.

According to the third embodiment, in RIE for forming the side wall spacers, etching in a necessary amount is performed in the low voltage transistor region. It is therefore possible to mitigate the influence of over-etching. In ion implantation for forming the low and intermediate concentration impurity regions, the acceleration energy is raised by an amount suitable for a thickness of the thickened gate insulating film. The acceleration energy is selected so that implanted impurity ions can reach the silicon substrate even through the thick gate insulating film.

FIGS. 5A to 5H are cross sectional views illustrating main processes of a semiconductor device manufacture method according to the fourth embodiment. Gate insulating films having different thicknesses and gate electrodes made of a lamination of a silicon layer and a silicide layer are formed by processes similar to those of the third embodiment.

As shown in FIG. 5A, a photoresist mask PR42 is formed opening n-channel transistor regions. P⁺ ions are implanted at an acceleration energy of 60 keV and a dose of 3×10¹³ cm⁻² to form low concentration impurity diffusion regions NLD1 and NLD2. The photoresist mask PR42 is thereafter removed.

As shown in FIG. 5B, a photoresist mask PR43 is formed opening the source region and intermediate concentration drain region, and a gate insulating film 12 is etched. P⁺ ions are implanted at an acceleration energy of 20 keV. The dose is determined depending upon desired characteristics. A thick gate insulating film 12x is selectively removed. Two P⁺ ion implantation processes form intermediate concentration impurity diffusion regions NMD. The photoresist mask PR43 is thereafter removed.

As shown in FIG. 5C, a photoresist mask PR44 is formed opening p-channel transistor regions. BF₂⁺ ions are implanted at an acceleration energy of 60 keV and a dose of 8×10¹³ cm⁻² to form low concentration impurity diffusion regions PLD1 and PLD2. The photoresist mask PR44 is thereafter removed.

As shown in FIG. 5D, a photoresist mask PR45 is formed opening the source region and an intermediate concentration drain region of a p-channel high voltage transistor, and the gate insulating film 12 is etched. B⁺ ions are implanted at an acceleration energy of 10 keV The dose is determined depending upon desired characteristics. Two ion implantation processes form an intermediate concentration impurity diffusion region PMD. The photoresist mask PR45 is thereafter removed.

As shown in FIG. 5E, a silicon oxide layer 16 having a thickness of 150 nm is formed by thermal CVD at a substrate temperature of 800° C.

As shown in FIG. 5F, RIE is performed to etch the silicon oxide layer 16 and thin gate insulating film 14. In the low voltage transistor regions, RIE forms side wall spacers 16x and etches the thin gate insulating film 14. In the high voltage transistor regions, the openings for intermediate concentration drain regions are already formed in the silicon oxide layer 16 so that side wall spacers 16y are formed on the side walls of the openings.

Over-etching is not necessary for the low voltage transistor region. In the high voltage transistor regions, the side wall spacers 16y are formed on the intermediate concentration regions, and the left openings can define a high concentration drain region.

As shown in FIG. 5G, a photoresist mask PR46 is formed opening the n-channel transistor regions. As⁺ ions are implanted at an acceleration energy of 70 keV and a dose of 4×10¹⁵ cm⁻² to form high concentration impurity diffusion regions NHD. The photoresist mask PR46 is thereafter removed.

As shown in FIG. 5H, a photoresist mask PR47 is formed having openings in regions corresponding to the p-channel transistor regions. BF₂⁺ ions are implanted at an acceleration energy of 60 keV and a dose of 3.5×10¹⁵ cm⁻² to form high concentration impurity diffusion regions PHD. The photoresist mask PR47 is thereafter removed.

In the fourth embodiment, the thick gate insulating film is etched by using the mask for forming the intermediate concentration impurity diffusion region. At the same time when the side wall spacers are formed for the gate electrode of the low voltage transistor, the side wall spacers are formed on the intermediate concentration impurity diffusion region of the high voltage transistor. A precision of the mask for forming the high concentration impurity diffusion region can be relaxed.

In the embodiments described above, the drain region of a high voltage transistor is formed by three stages for the low concentration impurity diffusion region, intermediate impurity diffusion region and high concentration impurity diffusion region. Depending upon desired characteristics, the drain region may be formed by two stages for the low and high concentration impurity diffusion regions.

FIGS. 6A to 6E are cross sectional views illustrating main processes of a semiconductor device manufacture method according to the fifth embodiment.

FIG. 6A illustrates a process corresponding to the process illustrated in FIG. 1F. The processes shown in FIGS. 1A to 1E are executed to form gate insulating films 12x and 14 having different thicknesses and gate electrodes G. A photoresist mask PR52 is formed having openings in regions corresponding to n-channel transistor regions. P⁺ ions are implanted at an acceleration energy of 20 keV and a dose of 4×10¹³ cm⁻² to form low concentration impurity diffusion regions NLD1 and NLD2. The photoresist mask PR52 is thereafter removed.

As shown in FIG. 6B, a photoresist mask PR53 is formed having openings in regions corresponding to p-channel transistor regions. BF₂⁺ ions are implanted at an acceleration energy of 35 keV and a dose of 3×10¹³ cm⁻² to form low concentration impurity diffusion regions PLD1 and PLD2. The photoresist mask PR53 is thereafter removed.

Similar to the first embodiment, the low concentration impurity diffusion regions NLD1 and PLD1 having a relatively high impurity concentration can be formed in the low voltage transistor region, and the low concentration impurity diffusion regions NLD2 and PLD2 having a relatively low impurity concentration can be formed in the low voltage transistor region, by the same ion implantation processes to be executed via the thick gate insulating film 12x and thin gate insulating film 14.

As shown in FIG. 6C, a silicon oxide layer 16 having a thickness of 120 nm is formed by thermal CVD at a substrate temperature of 800° C., and RIE is performed to form side wall spacers 16x. The gate insulating film 12x and 14 are etched at the same time.

As shown in FIG. 6D, a photoresist mask PR54 is formed covering the p-channel transistor regions and the low concentration drain region of the high voltage n-channel transistor region. As⁺ ions are implanted at an acceleration energy of 30 keV and a dose of 1×10¹⁵ cm⁻² to form high concentration impurity diffusion regions NHD. The photoresist mask PR54 is thereafter removed.

As shown in FIG. 6E, a photoresist mask PR55 is formed covering the n-channel transistor region and the low concentration drain region of the high voltage p-channel transistor region. BF₂⁺ ions are implanted at an acceleration energy of 20 keV and a dose of 3×10¹⁵ cm⁻² to form high concentration impurity diffusion regions PHD. The photoresist mask PR55 is thereafter removed.

In this manner, the semiconductor device is formed which includes high voltage transistors each having a low concentration drain region and a high concentration drain region. Thereafter, processes corresponding to the processes shown in FIGS. 1N to 1P are executed to complete the semiconductor device.

The present invention has been described in connection with the preferred embodiments. The invention is not limited only to the above embodiments. For example, it will be apparent to those skilled in the art that other various modifications, improvements, and combinations can be made.

### INDUSTRIAL APPLICABILITY

A multi-voltage semiconductor device using a plurality of voltages can be manufactured by simplified processes.

What we claim are:

1. A semiconductor device manufacture method comprising the steps of:
(a) forming a first gate insulating film having a first thickness in a first region of a semiconductor substrate;
(b) forming a second gate insulating film having a second thickness thinner than said first thickness in a second region of said semiconductor substrate;
(c) forming a gate electrode on said first and second gate insulating films and leaving said first and second gate insulating films in said first and second regions;
(d) implanting impurity ions into said first and second regions via said first and second gate insulating films to dope impurity ions in said first region at a first low concentration and in said second region at a second low concentration higher than said first low concentration;
(e) removing said first and second gate insulating films at least in regions where contacts are to be formed; and
(f) after removing said first and second gate insulating films, doping impurities at a high concentration in a region including the regions where the contacts are to be formed.

2. The semiconductor device manufacture method according to claim 1, further comprising the step of:
(g) doping impurities in a region spaced from said gate electrode in said first region via a mask.

3. The semiconductor device manufacture method according to claim 1, further comprising the step of:
(h) later than said step (d), depositing an auxiliary insulating film on said semiconductor substrate and performing anisotropic etching to form side wall spacers on side walls of at least said second gate electrode.

4. The semiconductor device manufacture method according to claim 3, wherein said step (h) forms side wall spacers also on side walls of said first gate electrode and anisotropically etches also said first and second gate insulating films.

5. The semiconductor device manufacture method according to claim 3, wherein said step (h) performs anisotropic etching after said auxiliary insulating film is deposited and said first region is covered with a mask, forms side wall spacers on side walls of said second gate electrode, and anisotropically etches also said second gate insulating film.

6. The semiconductor device manufacture method according to claim 5, wherein said step (e) etches said auxiliary insulating film in said first region, and then etches said first gate insulating film.

7. The semiconductor device manufacture method according to claim 2, further comprising the step of:
(h) later than said step (d), depositing an auxiliary insulating film on said semiconductor substrate, and anisotropically etching said auxiliary insulating film;
wherein said step (g) etches said auxiliary insulating film via a mask to form a contact opening, and thereafter dopes impurities, said step (h) forms side wall spacers on side walls of said second gate electrode and also on side walls of said auxiliary and second gate insulating films at said contact opening, and said step (f) implants impurity ions into regions defined by said side wall spacers.

8. A semiconductor device manufacture method comprising the steps of:
(a) forming a first gate insulating film having a first thickness in a first region of a semiconductor substrate;
(b) forming a second gate insulating film having a second thickness thinner than said first thickness in a second region of said semiconductor substrate;
(c) forming a gate electrode on said first and second gate insulating films, while leaving said first and second gate insulating films in said first and second regions;
(d) implanting impurity ions into said first region via said first gate insulating film to dope impurities at a first low concentration in said first region;
(e) doping impurities via a mask having openings in said second region and a region in said first region spaced from said gate electrode to form an intermediate concentration region in said first region and a low concentration region in said second region;
(f) removing said first and second gate insulating films at least in regions where contacts are to be formed; and
(g) after removing said first and second gate insulating films, doping impurities at a high concentration in a region including the regions where the contacts are to be formed.

9. A semiconductor device comprising:
a semiconductor substrate;
an isolation region formed in a surface of said semiconductor substrate, said isolation region defining first and second element regions;
a first gate insulating film formed on a surface of said first element region and having a first thickness;
a second gate insulating film formed on a surface of said second element region and having a second thickness thinner than said first thickness;
first and second gate electrode structures formed on said first and second gate insulating films and having first and second gate electrodes and first and second side wall spacers formed on side walls of said first and second gate electrodes;
a first low concentration region formed in said first element region outward from an edge of said first gate electrode;
a second low concentration region formed in said second element region outward from an edge of said second gate electrode;
a first intermediate concentration region formed spaced from the edge of said first gate electrode continuously with said first low concentration region in said first element region; and
first and second high concentration regions formed continuously with said first intermediate region and said second low concentration region in said first and second regions,
wherein a total sum of impurities doped in said first gate insulating film under said first side wall spacers and said first element region under said first gate insulating film is equal to a total sum of impurities doped in said second gate insulating film under said second side wall spacers and said second element region under said second gate insulating film.

10. A semiconductor device comprising:
a semiconductor substrate;
an isolation region formed in a surface of said semiconductor substrate, said isolation region defining first and second element regions;
a first gate insulating film formed on a surface of said first element region and having a first thickness;
a second gate insulating film formed on a surface of said second element region and having a second thickness thinner than said first thickness;
first and second gate electrode structures formed on said first and second gate insulating films and having first and second gate electrodes and first and second side wall spacers formed on side walls of said first and second gate electrodes;
a first low concentration region formed in said first element region outward from an edge of said first gate electrode;
a second low concentration region formed in said second element region outward from an edge of said second gate electrode; and
first and second high concentration regions formed continuously with said first and second low concentration regions in said first and second element regions,
wherein a total sum of impurities doped in said first gate insulating film under said first side wall spacers and said first region under said first gate insulating film is equal to a total sum of impurities doped in said second gate insulating film under said second side wall spacers and said second region under said second gate insulating film, and an amount of a total sum of impurities doped in said first high concentration region subtracted by a total sum of impurities doped in said first region under said first side wall spacers is equal to an amount of a total sum of impurities doped in said second high concentration region subtracted by a total sum of impurities doped in said second region under said second side wall spacers.
